(19) United States
(12) Patent Application Publication
(10) Pub. No.: US 2005/0169332 A1
(43) Pub. Date: Aug. 4, 2005

(54) Quantum dot gain chip

(76) Inventors: Jochen Schwarz, Stuttgart (DE); Tobias Ruf, Renningen (DE); Emmerich Mueller, Aidlingen (DE)

Correspondence Address: PERMAN & GREEN, 425 POST ROAD, FAIRFIELD, CT, 06824, US

(21) Appl. No.: 10/504,886

(22) PCT Filed: Jun. 10, 2002
(86) PCT No.: PCT/EP02/06310

(51) Int. Cl. H01S 5/00

(52) U.S. Cl. 372/43; 372/39; 438/22

(57) ABSTRACT

A gain chip for a laser includes a stack of layers. The stack has a first layer with light emitting quantum nanostructures of a first center emission wavelength, and a second layer on the first layer with light emitting quantum nanostructures of a second center emission wavelength.

### BACKGROUND OF THE INVENTION

The present invention relates to a gain chip for a laser, to a stack of layers to be incorporated in such a gain chip and to a method for fabricating the same.

Gain chips for lasers, stacks of layers to be incorporated in such a gain chip and methods for fabricating such stacks and gain chips for lasers are known from the prior art, e.g. from P. M. Varangis et al. “Low-threshold quantum dot lasers with 201 nm tuning range, Electronics Letters, 31^{st} August 2000, volume 36, number 18, from R. Heitz et al “Quantum size effect in self-organized InAs/GaAs quantum dots, Physical Review B, volume 62, number 16, Oct. 15, 2000, from R. H. Wang et al. “Room-temperature operation of InAs quantum-dash lasers on InP (001)”, IEEE Photonics Technology Letters, volume 13, no. 8, August 2001, from J. Shumway et al. “Electronic structure consequences of In/Ga composition variations in self-assembled InGa-As/Ga alloy quantum dots”, Physical Review B, volume 64, 125302, 2001, from R. Heitz et al. “Excited states and energy relaxation in stacked InAs/GaAs quantum dots”, Physical Review B, volume 57, number 15, Apr. 15, 1998, from Hakimi et al. in U.S. Pat. No. 5,260,957, from Nanbu et al. in U.S. Pat. No. 6,052,400, and from Sugiyama in U.S. Pat. No. 6,177,684 B1.

### SUMMARY OF THE INVENTION

It is an object of the invention to provide improved stacks of layers to be incorporated in a gain chip for a laser and methods for fabricating such structures.

The object is solved by the independent claims.

The term “nanostructure” in the present application means at least one of the following: quantum dots, quantum dashes, quantum wires, quantum wells.

The term “layer” in the present application generally includes layers with and without nanostructures unless otherwise defined.

The term “stack” in the present application means a sequence of layers.

The term “first layer” in the present application can but does not necessarily mean that this layer in the very first layer of a stack of layers. Rather than that the term “first” serves as a pure numbering tool in the claims.

The term “center emission wavelength” in the present application is defined as the maximum of the emission wavelength spectrum.

Quantum dots (QDs) are zero-dimensional nanostructures, i.e. nanostructures in which their electronic states are quantum confined in three dimensions.

Quantum dashes (QDashs) are elongated quantum dots.

Quantum wires are one-dimensional nanostructures, i.e. nanostructures in which their electronic states are quantum confined in two dimensions.

Quantum wells (QWs) are two-dimensional nanostructures, i.e. nanostructures in which their electronic states are quantum confined in one dimension.

An advantage of the present invention is an enhanced tuning range of the gain chips. This is made possible by the inventive combining of stacked layers of nanostructures, e.g. quantum dots, quantum dashes,. quantum wires, quantum wells with a certain size or with a certain emission wavelength range within each layer but different sizes or different emission wavelength ranges between different layers since the emission wavelength of such nanostructures depends on their size and/or the combination of elements that make the nanostructure.

Compared to quantum well laser structures, quantum dots have a longer carrier lifetime which leads to narrow-line width of the laser, have ultra-low line width enhancement factors, have increased temperature stability, have ultra-low threshold current density, have larger differential gain and allow higher band filling at low currents compared to quantum wells.

Dots need not be purely zero-dimensional objects in the mathematical sense. They have a physical shape that eventually leads to zero-dimensional behavior in the quantum-physical sense although their shape may be elongated, ellipsoidal or of similar structure. When talking about dots in the present application one-dimensional stripes or dashes, which demonstrate very similar, beneficial properties are also included.

In a preferred embodiment of the invention the same combination of elements is used for each nanostructure, e.g. dot in a certain layer of the stack and the same or different combinations of elements are used in different layers of the stack.

In a further preferred embodiment of the invention the variation of the quantum nanostructure size, e.g. dot size and/or the variation of the combination of elements between the layers is varied continuously in vertical direction through the stack.

In a preferred example of the present invention the nanostructure, e.g. dot diameter varies by 0.5 nm from layer to layer starting with a diameter of approximately 5 nm. In another preferred embodiment between 2 and 50 layers are used to build up a stack. It is preferred to use quantum nanostructures, e.g. dots having a height of approximately 1 to 5 nm. It is also preferred to use layers having a thickness of 3 to 6 nm.

Besides these examples emission at different wavelengths according to the invention (i.e., each layer has a specific center wavelength) can preferably be achieved by at least one of the following: nanostructures, e.g. dots of different size, dots of different alloy composition, nanostructures, e.g. dots with one chemical composition embedded in a matrix of another chemical composition, nanostructures, e.g. dots of different shapes in different layers.

Nanostructures, e.g. dots of different size can be realized by embedding InAs dots in GaAs, preferably by growing pyramids with base lengths 11-17 nm, and heights of 4-10 nm which yields to an emission wavelength between 1060 nm-1240 nm.

Nanostructures, e.g. dots of different alloy composition can preferably be realized by InₓGa₁₋ₓAs dots, with 0<×<1, preferably with 0.5<×<0.6, which yields to an emission wavelength between 980 nm and 1040 nm.

Nanostructures, e.g. dots with one chemical composition embedded in a matrix (e.g. in a bulk material or a quantum well) of another chemical composition can preferably be realized by using InAs/GaAs which yields to an emission wavelength between 1000 nm and 1250 nm, or by using InAs/GaInAsP or InAs/InGaAs which yields to an emission wavelength between 1000 nm and 1300 nm, or by using InAs/InP.

Nanostructures, e.g. dots of different shapes in different layers, can preferably be realized by layers of InAs/GaAs or by pyramids of InAs/InGaAs, which yields to an emission wavelength between 1000 nm and 1200 nm.

In each layer, the nanostructures, e.g. dots have an average density of 10¹⁰-10¹²/cm². The nanostructures may be regularly arranged or randomly distributed. Positional correlation between the nanostructures in different layers may but need not exist. The separation between the layers preferably ranges from 5-50 nm.

Each layer may contain nanostructures, e.g. dots with different emission wavelengths. The same emission wavelength may be produced by more than one of the layers. Examples: [λ₁, λ₂, λ₃] or [λ₁, λ₁, λ₂, λ₃] or [λ₁, λ₁, λ₂, λ₃, λ₃], λ₁, λ₂, λ₃ representing certain emission wavelengths.

The stacks or structures according to the present invention (i.e. having preferable combinations of emission wavelengths) may contain (i) only dots, (ii) a combination of dot layers and quantum well layers, (iii) dot layers embedded inside quantum wells, (iv) dot layers and quantum dash layers, (v) any combination and/or permutation of such and other suitable objects as long as the purpose of achieving a set of different preferable emission wavelengths is obtained.

In the proposed structures, the useful wavelength emission of the layers is mainly from the respective ground state excitons. Therefore, gain spectra can be engineered more easily than in prior art structures that involve higher excited states and a delicate balancing of the respective emission wavelengths to obtain a broad band gain (due to their more complex carrier filling behavior).

Preferable separations between the emission wavelengths (of the different layers) to obtain broad band gain in the proposed structures are between 0.2 and 0.7 of the smallest full-width at half maximum (FWHM) of each individual contribution to the emission.

Preferably, the gain spectra of the individual contributions add up to a gain curve of the resulting broadband gain medium which has desirable properties, e.g. a flat (constant) gain profile, a linearly increasing gain profile inclined towards shorter or longer wavelengths or a shape specifically adapted to purposes such as gain flattening or gain compensation.

In addition to their use in an external cavity laser, it is also possible to have other applications of the proposed structures, for example (i) other kinds of lasers (i.e., non-external cavity lasers, e.g. VCSELs), (ii) nonlasing elements, such as optical amplifiers or spontaneous emission sources (ASE) or (iii) light emitting diodes (LEDs).

The stacked quantum dots of the present invention can be used as a gain chip or gain material in a semiconductor laser. Furthermore, it is possible to use the inventive gain chips in external cavity lasers, e.g. Littman-type or Littrow-type cavity lasers.

The fabrication of the inventive structure can be done by epitaxial growth of the structure, e.g. by molecular beam epitaxy (MBE) or metal organic vapor phase epitaxy (MOVPE), using at least one of the following materials for the structure: InₓGa₁₋ₓAs/GaAs, InₓGa₁₋ₓAs/GaInAsP, InₓGaₗ₋ₓAs/InGaAs, InₓGaₗ₋ₓAs/InP, according to the scheme nanostructure material/layer material, with 0<×<1. The size of the dots can be controlled by varying the growth conditions, e.g. the pressure and/or the temperature and/or growth interruptions during the growth of the dot layer.

Other preferred embodiments are shown by the dependent claims.

It is clear that the invention can be partly embodied or supported by one or more suitable software programs, which can be stored on or otherwise provided by any kind of data carrier, and which might be executed (also in connection with the equipment used to provide the epitaxial growth) in or by any suitable data processing unit.

### BRIEF DESCRIPTION OF THE DRAWINGS

Other objects and many of the attendant advantages of the present invention will be readily appreciated and become better understood by reference to the following detailed description when considering in connection with the accompanied drawings. The components in the drawings are not necessarily to scale, emphasis instead being placed upon clearly illustrating the principles of the present invention. Features that are substantially or functionally equal or similar will be referred to with the same reference sign(s).

FIG. 1a shows a graph of a gain spectrum of a single dot layer of the prior art;

FIG. 1b shows a cross sectional view of a single dot layer of the prior art;

FIG. 2a shows, gain spectrum of a stacked dot layer with different dot sizes according to an embodiment of the present invention; and

FIG. 2b shows a stacked dot layers with different dot sizes according to an embodiment of the present invention;

FIG. 3 shows an external Littman-cavity laser with a gain chip according to the embodiment of FIG. 2b; and

FIG. 4 shows a Littrow-cavity-type laser with a gain chip according to the embodiment of FIG. 2b.

### DETAILED DESCRIPTION OF THE INVENTION

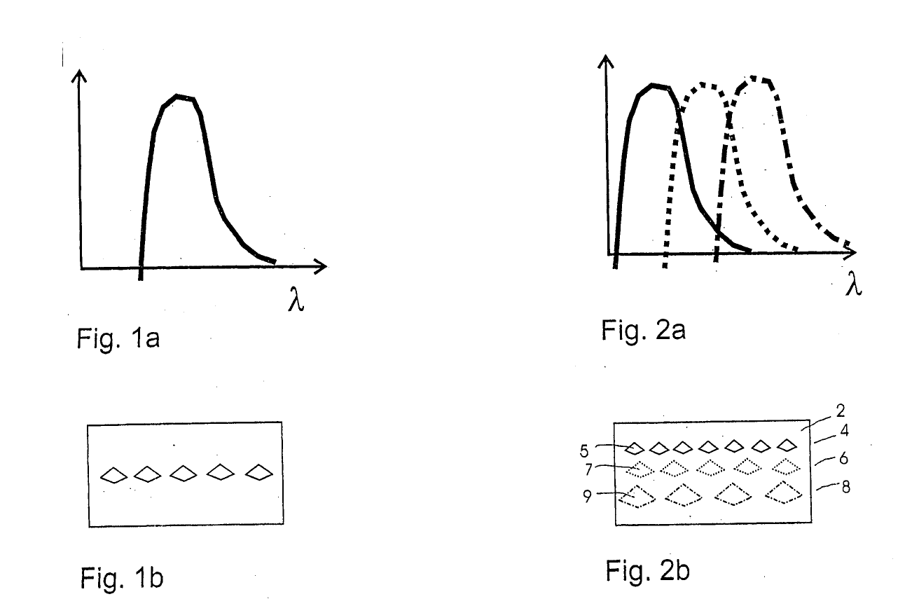

Referring now in greater detail to the drawings, FIG. 1a shows a gain spectrum of a single dot layer of the prior art according to FIG. 1b. The X-axis shows the gain while the Y-axis shows the wavelength of the light emission of the single dot layer. The spectrum of this prior art structure only covers a small range of wavelengths.

FIG. 2b shows a stack according to an embodiment of the present invention. According to FIG. 2b layer 4 contains dots 5 (shown in solid lines) forming pyramids with a base length of 11 nm and a height of 4 nm which yields to an emission wavelength of 1060 nm. Layer 6 contains dots 7 (shown in dotted lines) forming pyramids with a base length of 14 nm and a height of 7 nm which yields to an emission wavelength of 1150 nm. Layer 8 contains dots 9 (shown in dash-dot lines) in the form of pyramids with a base length 17 nm and a height of 10 nm which yields to an emission wavelength of 1240 nm. For this embodiment the used material system was InAs dots imbedded in a GaAs layer. When talking about center emission wavelength or emission wavelength it is meant the maximum wavelength of the emission wavelength spectrum according to FIG. 2a.

FIG. 2a shows a dot gain spectrum of a stack 2 of dot layers 4, 6 and 8 according to FIG. 2b. In FIG. 2a the emission wavelength of each layer is depicted with the same line type as the pyramids 5, 7 and 9 are depicted in FIG. 2b to show which emission spectrum corresponds to which pyramid 5, 7 and 9 and to which layer 4, 6 and 8. The gain spectra of the individual contributions add up to a gain curve which has the desired property, e.g., a flat gain profile.

Dots 5, 7 and 9 are made of InAs and are embedded in a matrix of GaAs. In each layer 4, 6 and 8 the dots 5, 7 and 9 have an average density of 10¹⁰-10¹²/cm². The dots are regularly arranged. Alternatively, a random arrangement is possible. A positional correlation between the dots 5, 7 and 9 in each layer 4, 6 and 8 does not exist. However, alternatively a positional correlation between the dots 5, 7 and 9 in different layers 4, 6 and 8 is possible. The separation between the layers 4, 6 and 8 can range from 5 to 50 nm. However, in the shown embodiment of FIG. 2b it is approximately 25 nm.

Stack 2 of the embodiment of FIG. 2b can be fabricated by epitaxial growth with the help of MBE. Alternatively, it is possible to use MOVPE. Instead of InAs as material for the dots it is also possible to use InₓGa₁₋ₓAs as material for the dots 5, 7 and 9, with 0<×<1.

The size of the dots 5, 7 and 9 is controlled by varying the growth conditions, e.g. the pressure and the temperature and/or growth interruptions during the growth of the dot layers 4, 6 and 8.

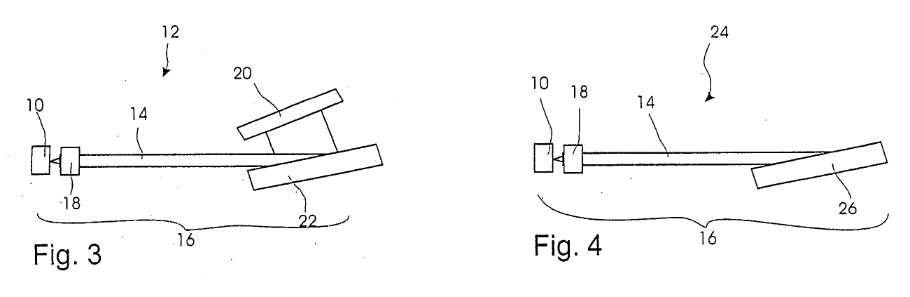

FIG. 3 shows a gain chip 10 with a stack 2 according to FIG. 2b in a Littman-type external cavity laser 12 according to another embodiment of the present invention. Laser 12 produces a beam 14 traveling in an external cavity 16. Beam 14 is focused by a lens 18 on the gain chip 10. An end mirror 20 and a diffractive grating 22 serve as tuning elements for the laser.

FIG. 4 shows the gain chip 10 in a Littrow-cavity-type external cavity laser 24 according to another embodiment of the present invention. An element 26 serves as a tuning and cavity end element.

1. A method of fabricating a stack (2) of layers (4, 6, 8) to be incorporated in a gain chip (10) for a laser (12, 24), comprising the steps of:
forming a first layer (4, 6, 8) comprising light emitting quantum nanostructures (5, 7, 9) of a first size,
forming a second layer (4, 6, 8) on the first layer (4, 6, 8) comprising light emitting quantum nanostructures (5, 7, 9) of a second size.

2. The method of claim 1, further comprising the steps of:
forming the layers (4, 6, 8) by epitaxial growth, preferably by MBE or MOVPE.

3. The method of claim 1 or any one of the above claims, further comprising the steps of:
forming the layers (4, 6, 8) by using at least one of the following materials for the nanostructures (5, 7, 9): InₓGa₁₋ₓAs/GaAs, InₓGa₁₋ₓAs/GaInAsP, InₓGa₁₋ₓAs/InGaAs, InₓGa₁₋ₓAs/InP, with 0<×<1.

4. The method of claim 1 or any one of the above claims, further comprising the steps of:
controlling the size of the nanostructures (5, 7, 9) by varying the growth conditions, preferably by at least one of the following growth conditions:
pressure during the growth of the layer (4, 6, 8), temperature during the growth of the layer (4, 6, 8) growth interruption

5. A software program or product, preferably stored on a data carrier, for executing the method of claim 1 or any one of the above claims when run on a data processing system such as a computer.

6. A stack of layers (4, 6, 8) to be incorporated in a gain chip (10) for a laser (12, 24), comprising:
a first layer (4, 6, 8) comprising light emitting quantum nanostructures (5, 7, 9) of a first size,
a second layer (4, 6, 8) on the first layer (4, 6, 8) comprising light emitting quantum nanostructures (5, 7, 9) of a second size.

7. The stack of claim 6,
wherein the nanostructures (5, 7, 9) in the same layer (4, 6, 8) having the same size.

8. The stack of claims 6 or 7,
wherein each nanostructure (5, 7, 9) in a certain layer (4, 6, 8) of the stack (2) comprises the same combination of elements but different layers (4, 6, 8) of the stack (2) comprise different combinations of elements.

9. The stack of claim 6 or any one of the above claims 7-8,
wherein a quantum nanostructure size is varied continuously or in steps between the layers (4, 6, 8) in vertical direction through the stack (2).

10. The stack of claim 6 or any one of the above claims 7-9,
wherein a combination of elements of a material for the nanostructures (5, 7, 9) is varied continuously or in steps between the layers (4, 6, 8) in vertical direction through the stack (2).

11. The stack of claim 6 or any one of the above claims 7-10,
wherein the nanostructure (5, 7, 9) diameter varies by approximately 0.5 nm from layer (4, 6, 8) to layer (4, 6, 8) starting with a diameter of approximately 5 nm or vice versa.

12. The stack of claim 6 or any one of the above claims 7-11,
wherein between 2< and 50 layers (4, 6, 8) are used to build up a stack (2).

13. The stack of claim 6 or any one of the above claims 7-12,
wherein the nanostructures (5, 7, 9) having a height of approximately 1-10 nm, preferably 4-5 nm.

14. The stack of claim 6 or any one of the above claims 7-13,
wherein the layers (4, 6, 8) having a thickness of 3 to 6 nm.

15. The stack of claim 6 or any one of the above claims 7-14,
wherein nanostructures (5, 7, 9) comprising InAs are embedded in layers (4, 6, 8) comprising GaAs.

16. The stack of claim 6 or any one of the above claims 7-15,
wherein the nanostructures (5, 7, 9) comprising pyramids with base lengths of approximately 11-17 nm.

17. The stack of claim 6 or any one of the above claims 7-16,
wherein the nanostructures (5, 7, 9) show varying alloy composition, preferably an alloy composition comprising InₓGa₁₋ₓAs with 0.5<×<0.6.

18. The stack of claim 6 or any one of the above claims 7-17,
wherein nanostructures (5, 7, 9) with one chemical composition are embedded in a layer (4, 6, 8) of another chemical composition, preferably by using at least on of the following material combinations: InₓGa₁₋ₓAs/GaAs, InₓGa₁₋ₓAs/GaInAsP, InₓGa₁₋ₓAs/InGaAs, InₓGa₁₋ₓAs/InP, according to the scheme nanostructure material/layer material, with 0<×<1.

19. The stack of claim 6 or any one of the above claims 7-18,
wherein in different layers (4, 6, 8) the nanostructures (5, 7, 9) have different shapes, preferably by layers (4, 6, 8) comprising at least one of the following materials: GaAs, InGaAs, and by nanostructures (5, 7, 9) comprising InAs.

20. The stack of claim 6 or any one of the above claims 7-19,
wherein in each layer (4, 6, 8) the nanostructures (5, 7, 9) have an average density of approximately 10¹⁰-10¹²/cm².

21. The stack of claim 6 or any one of the above claims 7-20,
wherein the nanostructures (5, 7, 9) are regularly arranged or randomly distributed in the layers (4, 6, 8).

22. The stack of claim 6 or any one of the above claims 7-21,
wherein a positional correlation between the nanostructures (5, 7, 9) in different layers (4, 6, 8) exists.

23. The stack of claim 6 or any one of the above claims 7-22,
wherein no positional correlation between the nanostructures (5, 7, 9) in different layers (4, 6, 8) exists.

24. The stack of claim 6 or any one of the above claims 7-23,
wherein a separation between the layers (4, 6, 8) preferably ranges from approximately 5-50 nm.

25. A stack of layers (4, 6, 8) to be incorporated in a gain chip (10) for a laser (12, 24), comprising:
a first layer (4, 6, 8) comprising light emitting quantum nanostructures (5, 7, 9) of a first center emission wavelength,
a second layer (4, 6, 8) on the first layer (4, 6, 8) comprising light emitting quantum nanostructures (5, 7, 9) of a second center emission wavelength.

26. The stack of claim 25 with the features of any one of the above claims 7-24.

27. A stack of layers (4, 6, 8) to be incorporated in a gain chip (10) for a laser (12, 24), comprising:
a first layer (4, 6, 8) comprising light emitting quantum nanostructures (5, 7, 9) of a first material composition,
a second layer (4, 6, 8) on the first layer (4, 6, 8) comprising light emitting quantum nanostructures (5, 7, 9) of a second material composition.

28. The stack of claim 27 with the features of any one of the above claims 7-24.

29. A gain chip for a laser (12, 24) comprising a stack of layers (4, 6, 8) according to, any one of the above claims 6-28.

30. A laser comprising a gain chip (10) comprising a stack of layers (4, 6, 8) according to any one of the above claims 6-28.

31. The laser of claim 30 comprising a semiconductor laser (12, 24).

32. The laser of claims 30 or 31 comprising an external cavity.

33. The laser of claim 30 or any one of the above claims 31-32 comprising a Littman or Littrow type cavity.

34. A method of fabricating a stack (2) of layers (4, 6, 8) to be incorporated in a gain chip (10) for a laser (12, 24), comprising the steps of:
forming a first layer (4, 6, 8) comprising light emitting quantum nanostructures (5, 7, 9) of a first center emission wavelength,
forming a second layer (4, 6, 8) on the first layer (4, 6, 8) comprising light emitting quantum nanostructures (5, 7, 9) of a second center emission wavelength.

35. The method of claim 34 with the features of any one of the above claims 2-4.

36. A method of fabricating a stack (2) of layers (4, 6, 8) to be incorporated in a gain chip (10) for a laser (12, 24), comprising the steps of:
forming a first layer (4, 6, 8) comprising light emitting quantum nanostructures (5, 7, 9) of a first material composition,
forming a second layer (4, 6, 8) on the first layer (4, 6, 8) comprising light emitting quantum nanostructures (5, 7, 9) of a second material composition.

37. The method of claim 36 with the features of any one of the above claims 2-4.
